(19) United States
(12) Patent Application Publication
(10) Pub. No.: US 2025/0261515 A1
(43) Pub. Date: Aug. 14, 2025

(54) DISPLAY APPARATUS

(71) Applicant: Samsung Display Co., LTD., Yongin-si (KR)

(72) Inventors: Wonhak CHOI, Yongin-si (KR); Gunwoo KO, Yongin-si (KR); Junghyun CHO, Yongin-si (KR); Beohmrock CHOI, Yongin-si (KR)

(21) Appl. No.: 18/793,610

(22) Filed: Aug. 2, 2024

(30) Foreign Application Priority Data
Feb. 13, 2024 (KR) 10-2024-0020673

(51) Int. Cl. H10K 59/122

(52) U.S. Cl. CPC H10K 59/122

(57) ABSTRACT

A display apparatus includes: a substrate; a first pixel electrode disposed on the substrate; a pixel-defining layer covering an edge of the first pixel electrode and defining a first pixel opening exposing a central portion of the first pixel electrode; an intermediate insulating layer interposed between the substrate and the pixel-defining layer and including a first portion defining a first intermediate opening having an area greater than an area of the first pixel opening in a plan view; a first intermediate layer contacting the first pixel electrode through the first pixel opening and including a first emission layer; and a common electrode disposed over the first pixel electrode with the first intermediate layer interposed therebetween and defining a plurality of first emission openings arranged outside the first pixel opening in the plan view.

This application claims priority to Korean Patent Application No. 10-2024-0020673, filed on Feb. 13, 2024, and all the benefits accruing therefrom under 35 U.S.C. § 119, the content of which in its entirety is herein incorporated by reference.

### BACKGROUND

### 1. Field

One or more embodiments relate to a display apparatus, more particularly, to a display apparatus on which a high-quality image is displayed.

### 2. Description of the Related Art

Display apparatuses may include a plurality of display devices and may display an image by using light emitted from the display devices. In such display apparatuses, the light extraction rate may be raised to facilitate outward extraction of light emitted from an emission layer included in a display device, which may lead to reduced power consumption of the display apparatuses.

### SUMMARY

Display apparatuses in related arts may not be capable of displaying a high-quality image without raising the light extraction rate.

To overcome various issues including the aforementioned one, one or more embodiments include a display apparatus on which a high-quality image is displayed. However, such technical aspect is provided merely as an example, and thus does not pose a limitation on the scope of the disclosure.

Additional aspects will be set forth in part in the description which follows and, in part, will be apparent from the description, or may be learned by practice of the presented embodiments of the disclosure.

According to one or more embodiments, a display apparatus includes: a substrate; a first pixel electrode disposed on the substrate; a pixel-defining layer covering an edge of the first pixel electrode and defining a first pixel opening exposing a central portion of the first pixel electrode; an intermediate insulating layer interposed between the substrate and the pixel-defining layer and including a first portion defining a first intermediate opening which is wider than the first pixel opening in a plan view; a first intermediate layer contacting the first pixel electrode through the first pixel opening and including a first emission layer; and a common electrode disposed over the first pixel electrode with the first intermediate layer interposed therebetween and defining a plurality of first emission openings arranged outside the first pixel opening in the plan view.

The first pixel electrode may extend over the first portion of the intermediate insulating layer.

The display apparatus may further include a thin-film transistor disposed under the first pixel electrode, where the first pixel electrode may be electrically connected to the thin-film transistor through a contact hole passing through the first portion of the intermediate insulating layer.

In the plan view, the plurality of first emission openings may be arranged along an edge of the first pixel opening.

In the plan view, a total area of first emission openings arranged on one side of the first pixel opening from among the plurality of first emission openings may be greater than a total area of first emission openings arranged on another side of the first pixel opening from among the plurality of first emission openings.

In the plan view, an area of each of first emission openings arranged on one side of the first pixel opening from among the plurality of first emission openings may be greater than an area of each of first emission openings arranged on another side of the first pixel opening from among the plurality of first emission openings.

In the plan view, a total number of first emission openings arranged on one side of the first pixel opening from among the plurality of first emission openings may be greater than a total number of first emission openings arranged on another side of the first pixel opening from among the plurality of first emission openings.

An area of each of the first emission openings arranged on one side of the first pixel opening from among the plurality of first emission openings may be equal to an area of each of the first emission openings arranged on another side of the first pixel opening from among the plurality of first emission openings in the plan view.

The plurality of first emission openings may have the same area from each other in the plan view.

In the plan view, an end of at least one of the plurality of first emission openings in a direction to the center portion of the first pixel electrode may be on the first pixel electrode.

In the plan view, an end of at least one of the plurality of first emission openings in a direction to the center portion of the first pixel electrode may be between an edge of the first intermediate opening and the edge of the first pixel electrode.

The intermediate insulating layer may further include a second portion interposed between the substrate and the first pixel electrode, disposed in the first intermediate opening in the plan view, and apart from the first portion.

An edge of the first portion in a direction to the second portion may include a first inclined portion inclining with respect to a major surface of the substrate, and an edge of the second portion may include a second inclined portion inclining with respect to the major surface of the substrate.

The second portion may define a recess or a hole corresponding to a center of the first pixel electrode.

An inner side surface of the recess or the hole defined in the second portion may include a third inclined portion inclining with respect to the major surface of the substrate.

The display apparatus may further include a second pixel electrode disposed on the substrate and a second intermediate layer contacting the second pixel electrode and including a second emission layer, where the pixel-defining layer may define a second pixel opening exposing a central portion of the second pixel electrode and may cover an edge of the second pixel electrode, and the common electrode may be disposed over the second pixel electrode with the second intermediate layer interposed therebetween and may define a plurality of second emission openings arranged outside the second pixel opening in the plan view.

From among layers included in the first intermediate layer, a layer other than the first emission layer may be integrally formed with a corresponding layer from among layers included in the second intermediate layer, other than the second emission layer.

In the plan view, a total area of first emission openings arranged on one side of the first pixel opening from among the plurality of first emission openings may be greater than a total area of first emission openings arranged on another side of the first pixel opening from among the plurality of first emission openings, and a total area of second emission openings arranged on one side of the second pixel opening from among the plurality of second emission openings may be less than a total area of second emission openings arranged on another side of the second pixel opening from among the plurality of second emission openings.

In the plan view, an area of each of first emission openings arranged on one side of the first pixel opening from among the plurality of first emission openings may be greater than an area of each of first emission openings arranged on another side of the first pixel opening from among the plurality of first emission openings, and an area of each of second emission openings arranged on one side of the second pixel opening from among the plurality of second emission openings may be less than an area of each of second emission openings arranged on another side of the second pixel opening from among the plurality of second emission openings.

In the plan view, a total number of first emission openings arranged on one side of the first pixel opening from among the plurality of first emission openings may be greater than a total number of first emission openings arranged on another side of the first pixel opening from among the plurality of first emission openings, and a total number of second emission openings arranged on one side of the second pixel opening from among the plurality of second emission openings may be less than a total number of second emission openings arranged on another side of the second pixel opening from among the plurality of second emission openings.

An area of each of the first emission openings arranged on one side of the first pixel opening from among the plurality of first emission openings may be equal to an area of each of the first emission openings arranged on another side of the first pixel opening from among the plurality of first emission openings, and an area of each of the second emission openings arranged on one side of the second pixel opening from among the plurality of second emission openings may be equal to an area of each of the second emission openings arranged on another side of the second pixel opening from among the plurality of second emission openings in the plan view.

The plurality of first emission openings may have the same area from each other, and the plurality of second emission openings may have the same area from each other in the plan view.

Other aspects, features, and advantages which are different than those described above will become apparent from the below detailed description, claims and drawings.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of a portion of a display apparatus according to an embodiment;

FIG. 2 is a schematic plan view of some components of the display apparatus of FIG. 1;

FIG. 3 is a schematic plan view of some components of a display apparatus according to an embodiment;

FIG. 4 is a schematic plan view of some components of a display apparatus according to an embodiment;

FIG. 5 is a schematic cross-sectional view of a portion of a display apparatus according to an embodiment;

FIG. 6 is a schematic cross-sectional view of a portion of a display apparatus according to an embodiment;

FIG. 7 is a schematic cross-sectional view of a portion of a display apparatus according to an embodiment;

FIG. 8 is a schematic plan view of some components of a display apparatus according to an embodiment;

FIG. 9 is a schematic plan view of some components of a display apparatus according to an embodiment; and

FIG. 10 is a schematic cross-sectional view of some components of a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As embodiments allow for various changes and numerous embodiments, exemplary embodiments will be illustrated in the drawings and described in detail in the written description. The effects, features of the disclosure and methods for achieving the same may be clarified by referring to the following detailed embodiments along with the drawings. The disclosure may, however, be embodied in many different forms and should not be construed as limited to the exemplary embodiments set forth herein.

Hereinafter, embodiments of the disclosure are explained in detail referring to the attached drawings. When referring to the drawings, like reference numerals may denote like or corresponding elements, and repeated descriptions thereof are omitted.

It will be understood that when a component, such as a layer, a film, a region, or a plate, is referred to as being “on” another component, the component can be directly on the other component or intervening components may be present thereon. Sizes of components in the drawings may be exaggerated or reduced for convenience of explanation. In other words, since sizes and thicknesses of components in the drawings are arbitrarily illustrated for convenience of explanation, the disclosure is not limited thereto.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

It will be understood that although terms such as “first” and “second” may be used herein to describe various components, these components should not be limited by these terms and these terms are only used to distinguish one component from another component.

In an embodiment below, it will be further understood that the terms “comprises” and/or “comprising” used herein specify the presence of stated features or components, but do not preclude the presence or addition of one or more other features or components.

As used herein, “A and/or B” represents the case of A, B, or A and B. Also, “at least one of A and B” represents the case of A, B, or A and B.

It will be understood that when a layer, region, or component is referred to as being “connected” to another layer, region, or component, it may be “directly connected” to the other layer, region, or component or may be “indirectly connected” to the other layer, region, or component with other layer, region, or component interposed therebetween. For example, it will be understood that when a layer, region, or component is referred to as being “electrically connected” to another layer, region, or component, it may be “directly electrically connected” to the other layer, region, or component or may be “indirectly electrically connected” to other layer, region, or component with other layer, region, or component interposed therebetween.

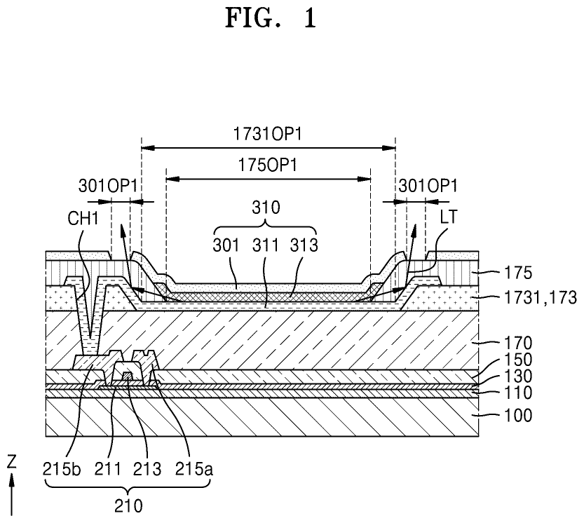

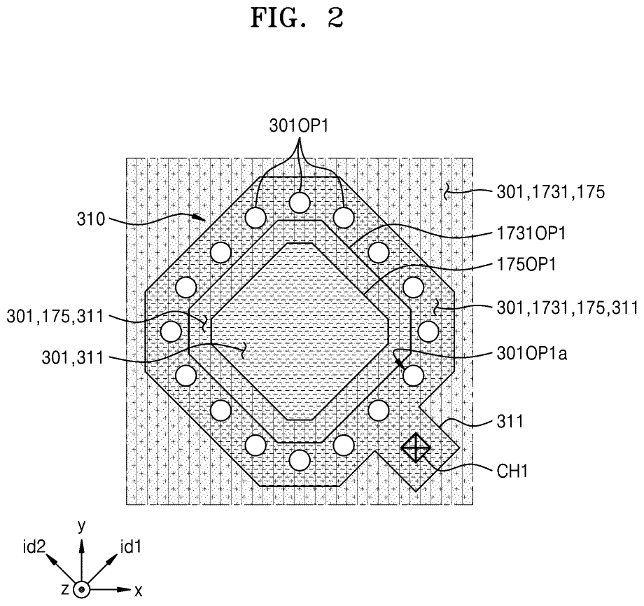

FIG. 1 is a schematic cross-sectional view of a display apparatus according to an embodiment, and FIG. 2 is a schematic plan view of some components of the display apparatus of FIG. 1. As used herein, the “plan view” is defined as a view seen from the direction (i.e., z-axis direction) perpendicular to a major surface (x-y plane) of the substrate 100.

A display apparatus according to an embodiment may include a substrate 100, a first organic light-emitting device 310, which is a first display device disposed on the substrate 100, and an encapsulation layer (not shown) covering the first organic light-emitting device 310.

The substrate 100 may include various materials having flexible or bendable characteristics, for example, polymer resin, such as polyethersulfone (“PES”), polyacrylate, polyetherimide (“PEI”), polyethylene naphthalate (“PEN”), polyethylene terephthalate (“PET”), polyphenylene sulfide (“PPS”), polyarylate (“PAR”), polyimide (“PI”), polycarbonate (“PC”), or cellulose acetate propionate (“CAP”). The substrate 100 may be modified in variously and may have a multi-layer structure including two layers including the aforementioned polymer resin and an inorganic material interposed between the two layers (e.g., silicon oxide, silicon nitride, or silicon oxynitride). Moreover, when the substrate 100 is not bendable, the substrate 100 may include glass, etc.

The first organic light-emitting device 310 may be disposed on the substrate 100, and a first pixel circuit electrically connected to the first organic light-emitting device 310 to control a degree of emission thereof may be interposed between the substrate 100 and the first organic light-emitting device 310. FIG. 1 illustrates one first thin-film transistor 210 which may be included in the first pixel circuit.

As illustrated in FIG. 1, the first thin-film transistor 210 may include a semiconductor layer 211 including amorphous silicon, polycrystalline silicon, or an organic semiconductor material, a gate electrode 213, a source electrode 215a, and a drain electrode 215b. Although FIG. 1 illustrates that the first thin-film transistor 210 includes the source electrode 215a and the drain electrode 215b, the disclosure is not limited thereto. For another example, the source electrode 215a and/or the drain electrode 215b may be a part of wiring. Or, the first thin-film transistor 210 may not include the source electrode 215a and/or the drain electrode 215b, and a source region and a drain region of the semiconductor layer 211 may serve as the source electrode and the drain electrode, respectively. For example, the first thin-film transistor 210 may not include a source electrode, and the source region of the semiconductor layer 211 of the first thin-film transistor 210 may be integrated with a drain region of another thin-film transistor. In this case, although the first thin-film transistor 210 does not include a source electrode, and the another thin-film transistor does not include a drain electrode, in a pixel circuit diagram, a drain electrode of the another thin-film transistor may be illustrated as being electrically connected to a source electrode of the first thin-film transistor 210. This may also be applied to embodiments described below and variations thereof.

To secure the insulating characteristics of the semiconductor layer 211 and the gate electrode 213, a gate insulating film 130 including an inorganic material, such as silicon oxide, silicon nitride, and/or silicon oxynitride may be interposed between the semiconductor layer 211 and the gate electrode 213. In addition, an interlayer-insulating film 150 including an inorganic material, such as silicon oxide, silicon nitride, and/or silicon oxynitride may be disposed on the gate electrode 213, and the source electrode 215a and the drain electrode 215b may be disposed on the interlayer-insulating film 150. An insulating film including an inorganic material may be formed by chemical vapor deposition (“CVD”) or atomic layer deposition (“ALD”). This may also be applied to embodiments described below and variations thereof.

A buffer layer 110 including an inorganic material, such as silicon oxide, silicon nitride, and/or silicon oxynitride may be interposed between the first thin-film transistor 210 and the substrate 100. The buffer layer 110 may increase the smoothness of a surface of the substrate 100 or prevent or minimize permeation of impurities from the substrate 100, etc. into the semiconductor layer 211 of the first thin-film transistor 210.

The gate electrode 213 may include, for example, a metal such as molybdenum, aluminum, etc. and may be formed by sputter, etc. The gate electrode 213 may have a single-layer structure or a multi-layer structure. For example, the gate electrode 213 may have a two-layer structure including Mo/Al.

The source electrode 215a and the drain electrode 215b may include a metal, such as titanium, aluminum, etc. and may have a single-layer or multi-layer structure. For example, the source electrode 215a and the drain electrode 215b may have a three-layer structure including titanium/aluminum/titanium.

A planarization layer 170 may be disposed on the first thin-film transistor 210. For example, as illustrated in FIG. 1, when the first organic light-emitting device 310 is disposed on the first thin-film transistor 210, the planarization layer 170 may generally planarize an upper portion of the first thin-film transistor 210. The planarization layer 170 may include, for example, an organic material, such as benzocyclobutene (“BCB”), hexamethyldisiloxane (“HMDSO”), etc. Although FIG. 1 illustrates the planarization layer 170 as having a single-layer structure, the planarization layer 170 may be variously modified and may have a multi-layer structure.

In a display region of the substrate 100, a first display device may be disposed on the planarization layer 170. The first display device may be, for example, the first organic light-emitting device 310 including a first pixel electrode 311, a common electrode 301, and a first intermediate layer 313 arranged therebetween and including a first emission layer.

As illustrated in FIG. 1, the first pixel electrode 311 may be in contact with any one of the source electrode 215a and the drain electrode 215b through a first contact hole CH1 formed in the planarization layer 170, etc. and may be electrically connected to the first thin-film transistor 210. The first pixel electrode 311 may include a transparent conductive layer including a transparent conductive oxide, such as ITO, In₂O₃, IZO, etc. and a reflective layer including a metal, such as Al, Ag, etc. For example, the first pixel electrode 311 may have a three-layer structure including ITO/Ag/ITO.

A pixel-defining layer 175 may be disposed on the planarization layer 170. The pixel-defining layer 175 may define a pixel by including a first pixel opening 175OP1 exposing a central portion of the first pixel electrode 311. In addition, as illustrated in FIG. 1, the pixel-defining layer 175 may prevent generation of arc, etc. at an edge of the first pixel electrode 311 by increasing a distance between the edge of the first pixel electrode 311 and the common electrode 301 on the first pixel electrode 311. The pixel-defining layer 175 may include an organic material such as polyimide or HMDSO.

An intermediate insulating layer 173 may be interposed between the substrate 100 and the pixel-defining layer 175, more specifically, between the planarization layer 170 and the pixel-defining layer 175. The intermediate insulating layer 173 may include a first portion 1731 as illustrated in FIG. 1. Similar to the pixel-defining layer 175 defining the first pixel opening 175OP1, the first portion 1731 of the intermediate insulating layer 173 may define a first intermediate opening 1731OP1. When seen from a direction perpendicular to the substrate 100 (z-axis direction), i.e., in a plan view, an area of the first intermediate opening 1731OP1 may be greater than an area of the first pixel opening 175OP1. That is, when seen from the direction perpendicular to the substrate 100 (z-axis direction), the first pixel opening 175OP1 may be arranged in the first intermediate opening 1731OP1.

The edge of the first pixel electrode 311 described above may be disposed on the first portion 1731 of the intermediate insulating layer 173. Accordingly, a part of the first pixel electrode 311 may be arranged on an inner side surface of the first intermediate opening 1731OP1, which is an inclined portion, as illustrated in FIG. 1. Moreover, as the area of the first intermediate opening 1731OP1 of the first portion 1731 of the intermediate insulating layer 173 is greater than the area of the first pixel opening 175OP1 of the pixel-defining layer 175 as described above, the pixel-defining layer 175 may cover a part of the first pixel electrode 311 arranged on the inner side surface of the first intermediate opening 1731OP1.

As described above, the first pixel electrode 311 may be in contact with any one of the source electrode 215a and the drain electrode 215b through the first contact hole CH1 formed in the planarization layer 170, etc. and may be electrically connected to the first thin-film transistor 210. As the first portion 1731 of the intermediate insulating layer 173 is interposed between the planarization layer 170 and the pixel-defining layer 175, the first contact hole CH1 may be formed not only in the planarization layer 170 but also in the first portion 1731 of the intermediate insulating layer 173. The first pixel electrode 311 may be electrically connected to the first thin-film transistor 210 through the first contact hole CH1.

The first intermediate layer 313 of the first organic light-emitting device 310 may include a low-molecular substance or a high-molecular substance. When the first intermediate layer 313 include a low-molecular substance, the first intermediate layer 313 may have a structure in which a hole injection layer (“HIL”), a hole transport layer (“HTL”), a first emission layer (“EML”), an electron transport layer (“ETL”), an electron injection layer (“EIL”) etc. are stacked in a single or combined structure and may be formed by vacuum deposition. When the first intermediate layer 313 include a high-molecular substance, the first intermediate layer 313 may have a structure including a HTL and an EML. In this case, the HTL may include poly(3,4-ethylenedioxythiophene) (“PEDOT”), and the EML may include a polymer material such as a polyphenylenevinylene (“PPV”)-based material, a polyfluorene-based material, etc. The first intermediate layer 313 may be formed through screen printing, inkjet printing, laser induced thermal imaging (“LITI”), etc.

However, the first intermediate layer 313 is not limited thereto and may have various other structures. The first emission layer of the first intermediate layer 313 may have a shape corresponding to the first pixel electrode 311; however, layers of the first intermediate layer 313 other than the first emission layer may be integrated over the first pixel electrode 311 and other pixel electrodes. The first intermediate layer 313 may be in contact with the first pixel electrode 311 through the first pixel opening 175OP1 of the pixel-defining layer 175.

The common electrode 301 may be disposed over the display region in which a plurality of display devices are arranged and cover the display region. That is, the common electrode 301 may be integrated with the first organic light-emitting device 310 and other organic light-emitting devices and may correspond to the first pixel electrode 311 and other pixel electrodes. The common electrode 301 may include a transparent conductive layer including ITO, In₂O₃, or IZO or may include a semi-transmissive film including a metal such as Al, Ag, etc. For example, the common electrode 301 may include a semi-transmissive film including MgAg.

As holes supplied from the first pixel electrode 311 and electrons supplied from the common electrode 301 form excitons in the first emission layer, the first organic light-emitting device 310 may generate light from the first emission layer. As such, a part of light generated from the first emission layer may proceed in a front direction (+z direction) of the display apparatus and may be extracted to the outside through the common electrode 301, and another part may proceed in a direction to the first pixel electrode 311 (−z direction) and may be reflected from the first pixel electrode 311 to proceed in the front direction (+z direction) and to be extracted to the outside through the common electrode 301.

Another part of the light generated from the first emission layer may proceed in a lateral direction. FIG. 1 illustrates an example of a travel route of light LT proceeding in the lateral direction. In the display apparatus according to an embodiment, as described above, a part of the first pixel electrode 311 may be arranged on the inner side surface of the first intermediate opening 1731OP1, which is an inclined portion. Accordingly, as illustrated in FIG. 1, the light LT proceeding in the lateral direction from the first emission layer may be reflected at a part of the first pixel electrode 311 arranged on the inner side surface of the first intermediate opening 1731OP1, which is an inclined portion and then proceed in the front direction (+z direction) of the display apparatus. In the display apparatus according to an embodiment, the common electrode 301 may define a plurality of first emission openings 301OP1 therein, and light reflected from a part of the first pixel electrode 311 arranged on the inner side surface of the first intermediate opening 1731OP1, which is an inclined portion, may be extracted to the outside through the first emission openings 301OP1 of the common electrode 301.

As described above, although the common electrode 301 includes a transparent conductive layer including ITO, In₂O₃, or IZO, not 100% of light incident onto the common electrode 301 may be transmitted through the common electrode 301. In addition, to increase the conductivity of the common electrode 301, the common electrode 301 may include in addition to a transparent conductive layer a semi-transmissive film including a metal such as Al, Ag, etc., and accordingly, the transmittance of the light incident onto the common electrode 301 may be further lowered.

However, in the display apparatus according to an embodiment, the common electrode 301 may include the plurality of first emission openings 301OP1 as described above. Accordingly, the light LT proceeding in the lateral direction from the first emission layer may be reflected from a portion of the first pixel electrode 311 arranged on the inner side surface of the first intermediate opening 1731OP1, which is an inclined portion, pass through the first emission openings 301OP1 of the common electrode 301 and then proceed in the front direction (+z direction) of display apparatus. Thus, by increasing the ratio of the light LT proceeding to the outside in the lateral direction from the first emission layer, the overall outward extraction of the light generated from the first emission layer may be increased.

More specifically, as illustrated in FIG. 2, when seen from the direction perpendicular to the substrate 100 (z-axis direction), i.e., in a plan view, the common electrode 301 may define the plurality of first emission openings 301OP1 arranged outside the first pixel opening 175OP1. The plurality of first emission openings 301OP1 may be arranged apart from each other. As described above, as holes supplied from the first pixel electrode 311 and electrons supplied from the common electrode 301 form excitons in the first emission layer, light may be generated from the first emission layer. Accordingly, the electrons may be smoothly provided to the first emission layer through the common electrode 301. In the display apparatus according to an embodiment, as the common electrode 301 has the plurality of first emission openings 301OP1, electrons may move through and between the plurality of first emission openings 301OP1 and smoothly migrate to the first emission layer.

Although FIG. 2 illustrates each of the plurality of first emission openings 301OP1 has a circular shape, the disclosure is not limited thereto. For another example, the shape may be changed to a tetragonal shape, etc., and a tetragonal shape and a circular shape may be used combinedly. This may also be applied to embodiments described below and variations thereof.

As illustrated in FIGS. 1 and 2, when seen from the direction perpendicular to the substrate 100 (z-axis direction), an end 301OP1a of at least one of the plurality of first emission openings 301OP1 in a direction to the center portion of the first pixel electrode 311 may be arranged on the first pixel electrode 311. More specifically, the end 301OP1a of the at least one of the plurality of first emission openings 301OP1 in the direction to the center portion of the first pixel electrode 311 may be arranged at an edge of the first intermediate opening 1731OP1 and an edge of the first pixel electrode 311. FIG. 2 illustrates that the end 301OP1a of each of the plurality of first emission openings 301OP1 in the direction to the center portion of the first pixel electrode 311 may be interposed between the edge of the first intermediate opening 1731OP1 and the edge of the first pixel electrode 311.

As described above, as holes supplied from the first pixel electrode 311 and electrons supplied from the common electrode 301 form excitons in the first emission layer, light may be generated from the first emission layer. Accordingly, the electrons may be smoothly provided to the first emission layer through the common electrode 301. To this end, by arranging the plurality of first emission openings 301OP1 of the common electrode 301 outside the first intermediate opening 1731OP1, electrons may be smoothly provided to the first emission layer from the common electrode 301 in the first pixel opening 175OP1 arranged in the first intermediate opening 1731OP1.

The plurality of first emission openings 301OP1 of the common electrode 301 may be arranged along the edge of the first pixel opening 175OP1, when seen from the direction perpendicular to the substrate 100 (z-axis direction), i.e., in a plan view. The plurality of first emission openings 301OP1 may have the same area from each other, and may be arranged at regular intervals. In FIG. 2, when seen from the direction perpendicular to the substrate 100 (z-axis direction), i.e., in a plan view, a direction between the x-axis direction and the y-axis direction is defined as the first inclination direction (+id1 direction), and a direction between the −x-axis direction and the y-axis direction is defined as the second inclination direction (+id2 direction). In FIG. 2, three first emission openings 301OP1 are arranged in the first inclination direction (+id1 direction) from the first pixel opening 175OP1, three first emission openings 301OP1 are arranged in the opposite direction (−id1 direction) of the first inclination direction from the first pixel opening 175OP1, three first emission openings 301OP1 are arranged in the second inclination direction (+id2 direction) from the first pixel opening 175OP1, three first emission openings 301OP1 are arranged in the opposite direction (−id2 direction) of the second inclination direction from the first pixel opening 175OP1, one first emission opening 301OP1 is arranged in each of +x direction, −x direction, +y direction, and −y direction from the first pixel opening 175OP1, and thus a plurality of first emission openings 301OP1 having the same area from each other are arranged at regular intervals.

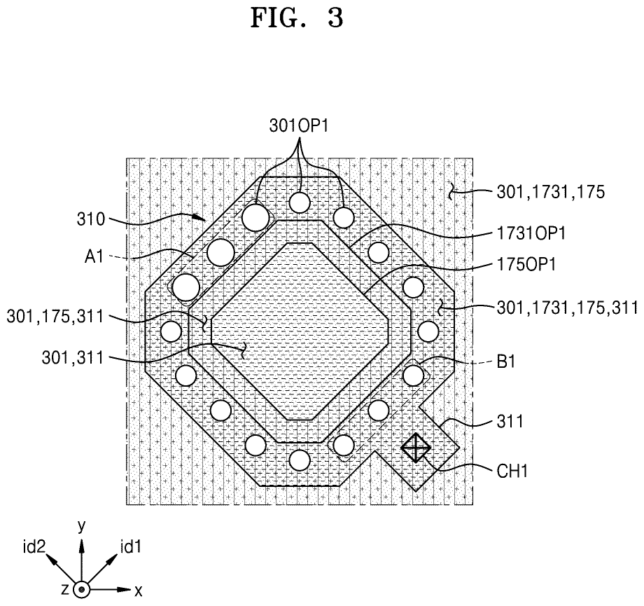

However, the disclosure is not limited thereto. For another example, as illustrated in the plan view of FIG. 3 schematically showing some components of the display apparatus according to an embodiment, when seen from the direction perpendicular to the substrate 100 (z-axis direction), i.e., in a plan view, the total area of the first emission openings arranged on one side of the first pixel opening 175OP1 in the second inclination direction (+id2 direction) from among the plurality of first emission openings 301OP1 may be greater than the total area of the first emission openings arranged on another side of the first pixel opening 175OP1 in the opposite direction (−id2 direction) of the second inclination direction. In FIG. 3, the total area of the first emission openings arranged in portion A1 from among the plurality of first emission openings 301OP1 is greater than the total area of the first emission openings arranged in portion B1 from among the plurality of first emission openings 301OP1. More specifically, in FIG. 3, an area of each of the first emission openings arranged in portion A1 from among the plurality of first emission openings 301OP1 is greater than an area of each of the first emission openings arranged in portion B1 from among the plurality of first emission openings 301OP1.

In an ideal display apparatus, even when a viewing angle at which the display region is seen changes, colors of an image displayed on the display region may not change. However, in an actual display apparatus, as the planarization layer 170 may not be completely flat, and thus pixel electrodes may incline, when a viewing angle at which the display region is seen changes, colors of an image displayed on the display region may change.

In the display apparatus according to the embodiment, as described above in relation to FIG. 3, the total area of the first emission openings arranged in a particular portion, e.g., portion A1, from among the plurality of first emission openings 301OP1 may be greater than the total area of the first emission openings arranged in another particular portion, e.g., portion B1, from among the plurality of first emission openings 301OP1. Accordingly, in the first organic light-emitting device 310, portion A1 may emit a relatively greater amount of light than portion B1. This eventually means that when seen from the second inclination direction (+id2 direction) in which portion A1 is located with respect to the center of the first organic light-emitting device 310, colors of light emitted from the first organic light-emitting device 310 may be more visible than when seen from the opposite direction (−id2 direction) of the second inclination direction in which portion B1 is located with respect to the center of the first organic light-emitting device 310.

As such, as the total area of the first emission openings arranged on one side of the first pixel opening 175OP1 from among the plurality of first emission openings 301OP1 is greater than the total area of the first emission openings arranged on another side of the first pixel opening 175OP1, even when the viewing angle at which the display region is seen changes, colors of an image displayed on the display region may not substantially change, or the change may be minimized. That is, if color of an image displayed on the display region changes according to the change of the viewing angle because the planarization layer 170 is not completely flat and thus pixel electrodes incline, it is possible to minimize such color change by changing the total area of the first emission openings arranged on one side of the first pixel opening 175OP1.

As described above, in FIG. 3, the area of each of the first emission openings arranged in portion A1 from among the plurality of first emission openings 301OP1 is greater than the area of each of the first emission openings arranged in portion B1 from among the plurality of first emission openings 301OP1. However, the disclosure is not limited thereto.

For example, unlike the description of FIG. 3, the total area of the first emission openings arranged in portion B1 from among the plurality of first emission openings 301OP1 may be less than the total area of the first emission openings arranged in portion A1 from among the plurality of first emission openings 301OP1. More specifically, the area of each of the first emission openings arranged in portion B1 from among the plurality of first emission openings 301OP1 may be less than the area of each of the first emission openings arranged in portion A1 from among the plurality of first emission openings 301OP1. In this case, the area of each of the first emission openings arranged in portions other than portion A1 and portion B1 from among the plurality of first emission openings 301OP1 may be identical to the area of each of the first emission openings arranged in portion A1. As such, as the area of each of the first emission openings arranged in portion B1 from among the plurality of first emission openings 301OP1 is less than the area of each of the first emission openings arranged in other portions, even when the viewing angle at which the display region is seen changes, colors of an image displayed on the display region may not substantially change, or the change may be minimized. This may also be applied to embodiments described below and variations thereof.

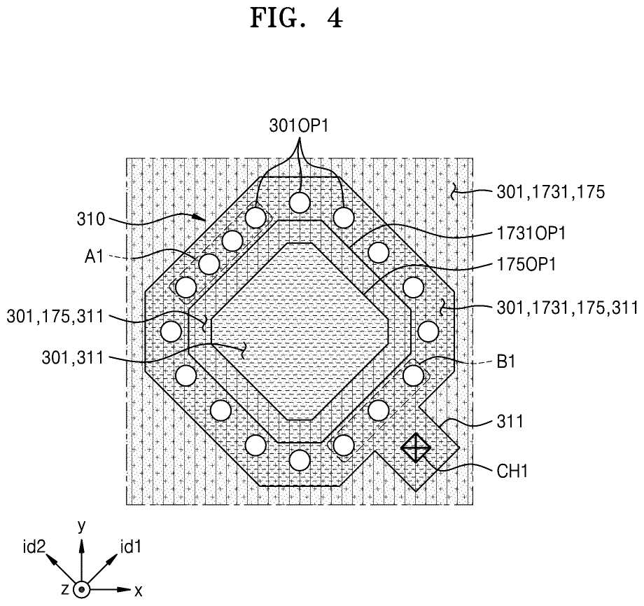

Or, as illustrated in the plan view of FIG. 4 schematically showing some components of the display apparatus according to an embodiment, when seen from the direction perpendicular to the substrate 100 (z-axis direction), i.e., in a plan view, the number of the first emission openings arranged on one side of the first pixel opening 175OP1 in the second inclination direction (+id2 direction) from among the plurality of first emission openings 301OP1 may be greater than the number of the first emission openings arranged on another side of the first pixel opening 175OP1 in the opposite direction (−id2 direction) of the second inclination direction. In FIG. 4, the number of the first emission openings arranged in portion A1 from among the plurality of first emission openings 301OP1 is greater than the number of the first emission openings arranged in portion B1 from among the plurality of first emission openings 301OP1.

Accordingly, in the first organic light-emitting device 310, portion A1 may emit a relatively greater amount of light than portion B1. This eventually means that when seen from the second inclination direction (+id2 direction) in which portion A1 is located with respect to the center of the first organic light-emitting device 310, colors of light emitted from the first organic light-emitting device 310 may be more visible than when seen from the opposite direction (−id2 direction) of the second inclination direction in which portion B1 is located with respect to the center of the first organic light-emitting device 310.

As such, as the number of the first emission openings arranged on one side of the first pixel opening 175OP1 in the second inclination direction (+id2 direction) from among the plurality of first emission openings 301OP1 is greater than the number of the first emission openings arranged on another side of the first pixel opening 175OP1 in the opposite direction (−id2 direction) of the second inclination direction, even when the viewing angle at which the display region is seen changes, colors of an image displayed on the display region may not substantially change, or the change may be minimized.

In this case, as illustrated in FIG. 4, the plurality of first emission openings 301OP1 may have the same area from each other. Or, the area of each of the first emission openings arranged in portion A1 from among the plurality of first emission openings 301OP1 may be identical to the area of each of the first emission openings arranged in portion B1 from among the plurality of first emission openings 301OP1. Alternatively, while the structure of FIG. 4 is maintained, the area of each of the first emission openings arranged in portion A1 from among the plurality of first emission openings 301OP1 may be greater than the area of each of the first emission openings arranged in portion B1 from among the plurality of first emission openings 301OP1 in a plan view.

Unlike the description of FIG. 4, the number of the first emission openings arranged in portion B1 from among the plurality of first emission openings 301OP1 may be smaller than the number of the first emission openings arranged in portion A1 from among the plurality of first emission openings 301OP1. In this case, the number of the first emission openings arranged on one side of the first pixel opening 175OP1 in the first inclination direction (+id1 direction) from among the plurality of first emission openings 301OP1 and the number of the first emission openings arranged on another side of the first pixel opening 175OP1 in the opposite direction (−id1 direction) of the first inclination direction may be identical to the number of the first emission openings arranged in portion A1. As such, as the number of the first emission openings arranged in portion B1 from among the plurality of first emission openings 301OP1 is smaller than the number of the first emission openings arranged in other portions, even when the viewing angle at which the display region is seen changes, colors of an image displayed on the display region may not substantially change, or the change may be minimized. This may also be applied to embodiments described below and variations thereof.

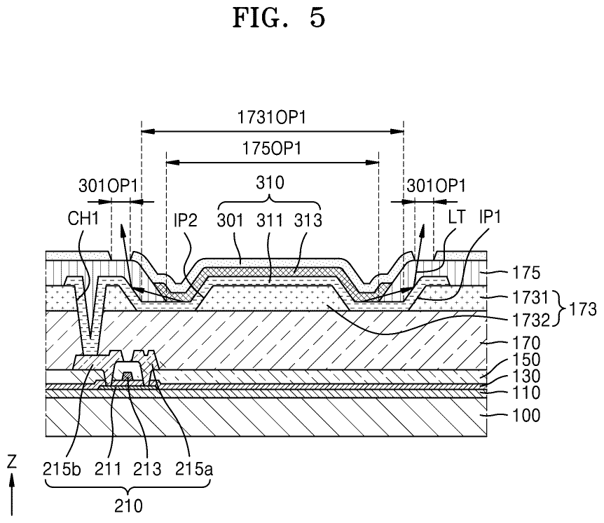

FIG. 5 is a schematic cross-sectional view of a portion of the display apparatus according to an embodiment. The display apparatus according to the embodiment may be different from the display apparatus described above in relation to FIG. 1 in that the intermediate insulating layer 173 further includes a second portion 1732 in addition to the first portion 1731. The second portion 1732 may be interposed between the substrate 100 and the first pixel electrode 311, more specifically, between the planarization layer 170 and the first pixel electrode 311. The second portion 1732 may be arranged in the first intermediate opening 1731OP1 and may be arranged apart from the first portion 1731.

As described above, the edge of the first pixel electrode 311 may be disposed over the first portion 1731 of the intermediate insulating layer 173. Accordingly, a part of the first pixel electrode 311 may be arranged on the inner side surface of the first intermediate opening 1731OP1, which is a first inclined portion IP1. That is, the first inclined portion IP1 may be an edge of the first portion 1731 in the direction to the second portion 1732, and the first inclined portion IP1 may be a surface inclining with respect to the major surface (i.e., plane made by x-axis and y-axis) of the substrate 100. Similarly, an edge of the second portion 1732 which may have a shape of an island may include a second inclined portion IP2 inclining with respect to the major surface of the substrate 100.

In the display apparatus according to the embodiment, due to the presence of the second inclined portion IP2, a greater amount of light generated from the first emission layer included in the first intermediate layer 313 may be directed to a portion of the first pixel electrode 311 arranged on the first inclined portion IP1. Accordingly, by increasing an amount of light extracted to the outside through the first emission openings 301OP1 of the common electrode 301, the luminance of an image implemented by the display apparatus may be improved without causing an increase in power consumption of the display apparatus.

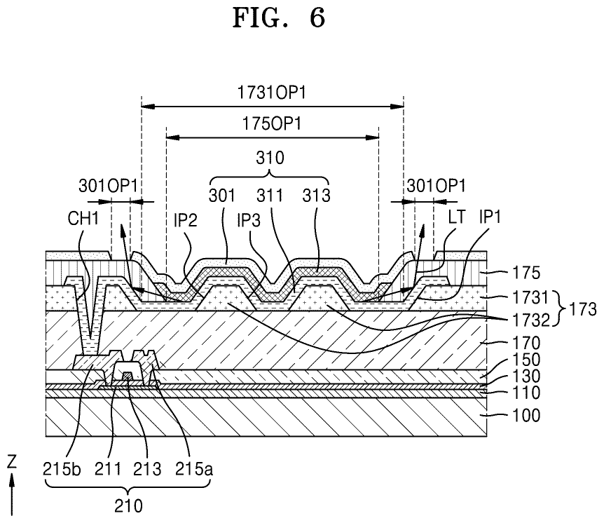

Moreover, as illustrated in FIG. 2 schematically showing a cross-sectional view of a part of the display apparatus according to an embodiment, the second portion 1732 of the intermediate insulating layer 173 may define a recess or a hole which correspond to the center of the first pixel electrode 311. In an embodiment, FIG. 6 illustrates that the second portion 1732 defines a hole, and the first pixel electrode 311 is in contact with the planarization layer 170 through the hole. An inner side surface of the recess or the hole may include a third inclined portion IP3 inclining with respect to the major surface of the substrate 100.

Although the first organic light-emitting device 310, which is a first display device, is described in detail so far, the same or similar descriptions on the first display apparatus may also be applied to other display apparatuses. Hereinafter, a second organic light-emitting device is described along with the first organic light-emitting device 310.

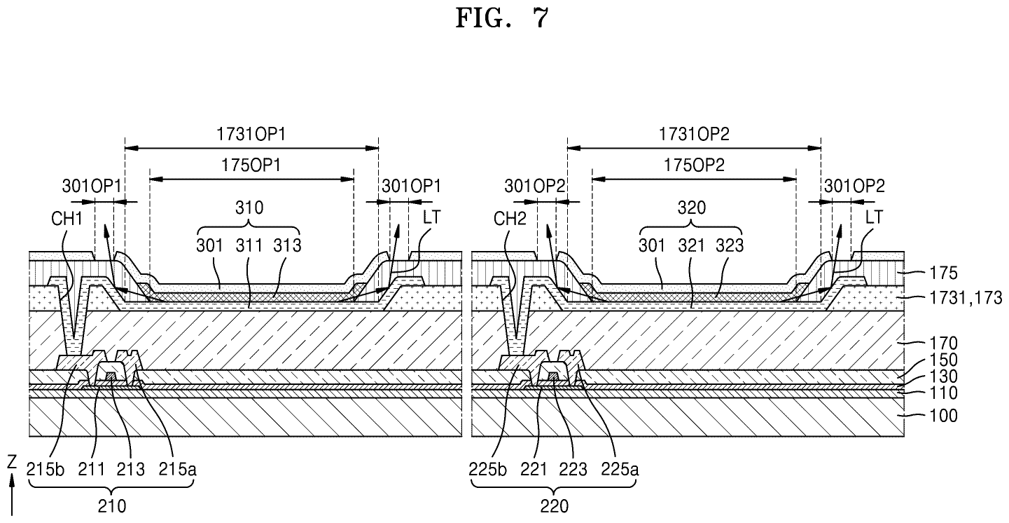

FIG. 7 is a schematic cross-sectional view of a portion of the display apparatus according to an embodiment. In addition to the first organic light-emitting device 310 described above, FIG. 7 illustrates a second thin-film transistor 220 and a second organic light-emitting device 320 electrically connected to the second thin-film transistor 220.

Similar to the first thin-film transistor 210, the second thin-film transistor 220 may include a semiconductor layer 221, a gate electrode 223, a source electrode 225a, and a drain electrode 225b. As the descriptions about the components of the first thin-film transistor 210 may also be applied to the components of the second thin-film transistor 220, any redundant description thereon may be omitted.

The second organic light-emitting device 320 may be arranged a second pixel electrode 321, the common electrode 301, and a second intermediate layer 323 arranged therebetween and including a second emission layer. The second pixel electrode 321 may be electrically connected to the second thin-film transistor 220 through a second contact hole CH2 formed in the first portion 1731 of the intermediate insulating layer 173 and the planarization layer 170. The descriptions on the first pixel electrode 311 and the first intermediate layer 313 may be applied to the second pixel electrode 321 and the second intermediate layer 323 as well.

Although FIG. 7 illustrates that first intermediate layer 313 and the second intermediate layer 323 are arranged apart from each other for convenience, the disclosure is not limited thereto. The first emission layer of the first intermediate layer 313 may have an island shape corresponding to the first pixel electrode 311, and the second emission layer of the second intermediate layer 323 may have an island shape corresponding to the second pixel electrode 321. However, each of layers of the first intermediate layer 313 other than the first emission layer may be integrated with a corresponding layer from among layers of the second intermediate layer 323 other than the second emission layer.

The pixel-defining layer 175 may define a pixel by including a second pixel opening 175OP2 exposing a central portion of the second pixel electrode 321. As described above, as the first portion 1731 of the intermediate insulating layer 173 may be interposed between the planarization layer 170 and the pixel-defining layer 175, the first portion 1731 of the intermediate insulating layer 173 may define a second intermediate opening 1731OP2. When seen from the direction perpendicular to the substrate 100 (z-axis direction), i.e., in a plan view, an area of the second intermediate opening 1731OP2 may be greater than an area of the second pixel opening 175OP2. That is, when seen from the direction perpendicular to the substrate 100 (z-axis direction), the second pixel opening 175OP2 may be arranged in the second intermediate opening 1731OP2. Similar to the first pixel electrode 311, an edge of the second pixel electrode 321 may be disposed over the first portion 1731 of the intermediate insulating layer 173. Accordingly, a part of the second pixel electrode 321 may be arranged on an inner side surface of the second intermediate opening 1731OP2, which is an inclined portion, as illustrated in FIG. 7.

In the display apparatus according to the embodiment, as the common electrode 301 defines second emission openings 301OP2 in addition to the first emission openings 301OP1, light reflected from a portion of the second pixel electrode 321 arranged on the inner side surface of the second intermediate opening 1731OP2, which is an inclined portion, may be extracted to the outside through the second emission openings 301OP2 of the common electrode 301. Accordingly, the light extraction efficiency may increase in the second organic light-emitting device 320.

As illustrated in FIG. 7, when seen from the direction perpendicular to the substrate 100 (z-axis direction), i.e., in a plan view, the common electrode 301 may define the plurality of second emission openings 301OP2 arranged outside the second pixel opening 175OP2. The plurality of second emission openings 301OP2 may be arranged apart from each other. As holes supplied from the second pixel electrode 321 and electrons supplied from the common electrode 301 form excitons in the second emission layer, light may be generated from the second emission layer. Accordingly, the electrons may be smoothly provided to the second emission layer through the common electrode 301. In the display apparatus according to an embodiment, as the common electrode 301 has the plurality of second emission openings 301OP2, electrons may move through and between the plurality of second emission openings 301OP2 and smoothly migrate to the second emission layer.

When seen from the direction perpendicular to the substrate 100 (z-axis direction), the descriptions on the positions of the plurality of first emission openings 301OP1 with respect to the first pixel electrode 311 or the first intermediate opening 1731OP1 may also be applied to positions of the plurality of second emission openings 301OP2 with respect to the second pixel electrode 321 or the second intermediate opening 1731OP2. Accordingly, any redundant description thereon may be omitted.

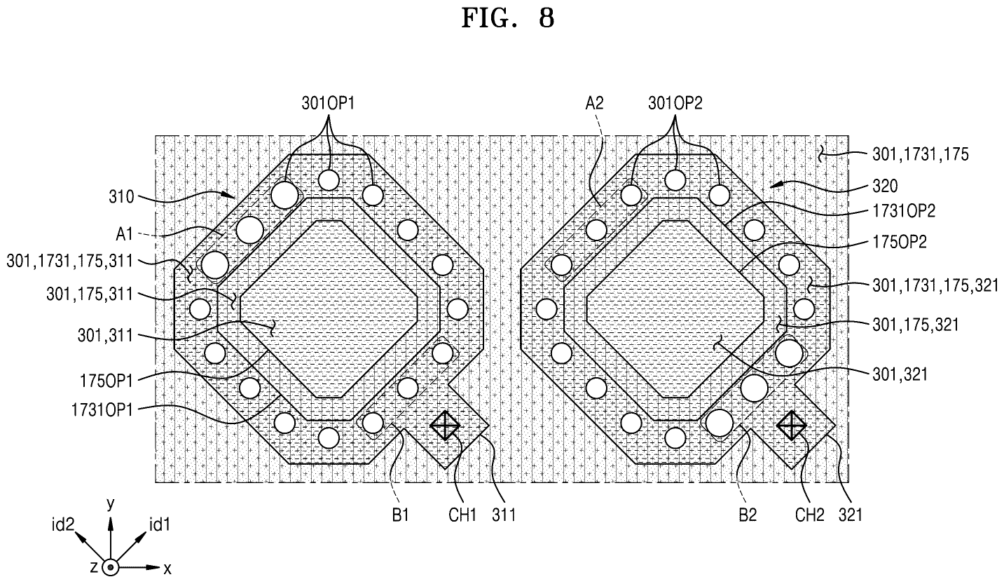

FIG. 8 is a schematic plan view of some components of the display apparatus according to an embodiment. FIG. 8 illustrates that, when seen from the direction perpendicular to the substrate 100 (z-axis direction), i.e., in a plan view, a total area of first emission openings arranged on one side of the first pixel opening 175OP1 in the second inclination direction (+id2 direction) from among the plurality of first emission openings 301OP1 is greater than a total area of first emission openings arranged on another side of the first pixel opening 175OP1 in the opposite direction (−id2 direction) of the second inclination direction. That is, in FIG. 8, the total area of the first emission openings arranged in portion A1 from among the plurality of first emission openings 301OP1 is greater than the total area of the first emission openings arranged in portion B1 from among the plurality of first emission openings 301OP1. More specifically, in FIG. 8, an area of each of the first emission openings arranged in portion A1 from among the plurality of first emission openings 301OP1 is greater than an area of each of the first emission openings arranged in portion B1 from among the plurality of first emission openings 301OP1.

Moreover, FIG. 8 illustrates that, when seen from the direction perpendicular to the substrate 100 (z-axis direction), i.e., in a plan view, a total area of second emission openings arranged on one side of the second pixel opening 175OP2 in the opposite direction (−id2 direction) of the second inclination direction from among the plurality of second emission openings 301OP2 is greater than a total area of second emission openings arranged on another side of the second pixel opening 175OP2 in the second inclination direction (+id2 direction). That is, in FIG. 8, the total area of the second emission openings arranged in portion B1 from among the plurality of second emission openings 301OP2 is greater than the total area of the second emission openings arranged in portion A2 from among the plurality of second emission openings 301OP2. More specifically, in FIG. 8, an area of each of the second emission openings arranged in portion B2 from among the plurality of second emission openings 301OP2 is greater than an area of each of the second emission openings arranged in portion A2 from among the plurality of second emission openings 301OP2.

For example, the first organic light-emitting device 310 may be the first display apparatus emitting red light, and the second organic light-emitting device 320 may be the second display apparatus emitting blue light. In this case, red light may be emitted relatively more from portion A1 than from portion B1, and blue light may be emitted relatively more from portion B2 than from portion A2. Accordingly, when the display region is seen from the second inclination direction (+id2 direction), red light may be relatively more visible, and when the display region is seen from the opposite direction (−id2 direction) of the second inclination direction, blue light may be relatively more visible. When the first emission openings 301OP1 have the same area from each other, the second emission openings 301OP2 have the same area from each other, and the colors of a displayed image change according to a viewing angle, through such adjustment, the color change of the displayed image according to a viewing image may be minimized.

FIG. 8 illustrates that the area of each of the first emission openings arranged in portion A1 from among the plurality of first emission openings 301OP1 is greater than the area of each of the first emission openings arranged in portion B1 from among the plurality of first emission openings 301OP1, and the area of each of the second emission openings arranged in portion B2 from among the plurality of second emission openings 301OP2 is greater than the area of each of the second emission openings arranged in portion A2 from among the plurality of second emission openings 301OP2. However, the disclosure is not limited thereto.

For example, unlike the description of FIG. 8, the area of each of the first emission openings arranged in portion B1 from among the plurality of first emission openings 301OP1 may be less than the area of each of the first emission openings arranged in portion A1 from among the plurality of first emission openings 301OP1, and the area of each of the second emission openings arranged in portion A2 from among the plurality of second emission openings 301OP2 may be less than the area of each of the second emission openings arranged in portion B2 from among the plurality of second emission openings 301OP2 in a plan view. In this case, an area of each of first emission openings arranged in portions other than portions A1 and B1 from among the plurality of first emission openings 301OP1 may be identical to the area of each of the first emission openings arranged in portion A1, and an area of each of second emission openings arranged in portions other than portions A2 and B2 from among the plurality of second emission openings 301OP2 may be identical to the area of each of the second emission openings arranged in portion B2. Through such configuration, even when the viewing angle at which the display region is seen changes, colors of an image displayed on the display region may not substantially change, or the change may be minimized. This may also be applied to embodiments described below and variations thereof.

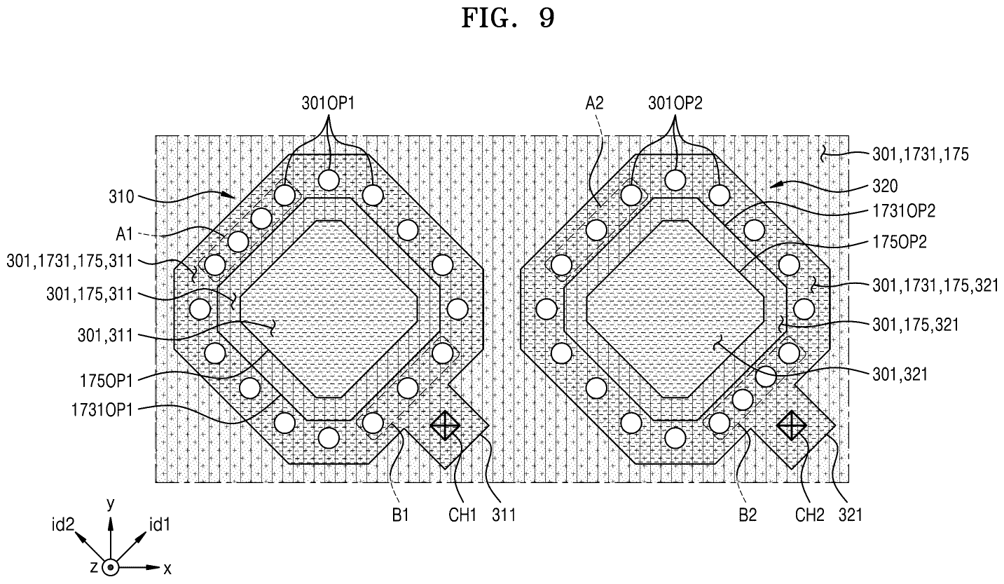

Or, as illustrated in the plan view of FIG. 9 schematically showing some components of the display apparatus according to an embodiment, when seen from the direction perpendicular to the substrate 100 (z-axis direction), i.e., in a plan view, the number of the first emission openings arranged on one side of the first pixel opening 175OP1 in the second inclination direction (+id2 direction) from among the plurality of first emission openings 301OP1 may be greater than the number of the first emission openings arranged on another side of the first pixel opening 175OP1 in the opposite direction (−id2 direction) of the second inclination direction. In addition, the number of the second emission openings arranged on side of the second pixel opening 175OP2 in the opposite direction (−id2 direction) of the second inclination direction from among the plurality of second emission openings 301OP2 may be greater than the number of the second emission openings arranged on another side of the second pixel opening 175OP2 in the second inclination direction (+id2 direction). FIG. 9 illustrates that the number of the first emission openings arranged in portion A1 from among the plurality of first emission openings 301OP1 is greater than the number of the first emission openings arranged in portion B1 from among the plurality of first emission openings 301OP1, and the number of the second emission openings arranged in portion B2 from among the plurality of second emission openings 301OP2 is greater than the number of the second emission openings arranged in portion A2 from among the plurality of second emission openings 301OP2.

For example, the first organic light-emitting device 310 may be the first display apparatus emitting red light, and the second organic light-emitting device 320 may be the second display apparatus emitting blue light. In this case, red light may be emitted relatively more from portion A1 than from portion B1, and blue light may be emitted relatively more from portion B2 than from portion A2. Accordingly, when the display region is seen from the second inclination direction (+id2 direction), red light may be relatively more visible, and when the display region is seen from the opposite direction (−id2 direction) of the second inclination direction, blue light may be relatively more visible. Through such adjustment, a color change of a displayed image according to a viewing angle may be minimized.

In this case, as illustrated in FIG. 9, the plurality of first emission openings 301OP1 may have the same area from each other, and the plurality of second emission openings 301OP2 may have the same area from each other.

Or, unlike the description of FIG. 9, the number of the first emission openings arranged in portion B1 from among the plurality of first emission openings 301OP1 may be smaller than the number of the first emission openings arranged in portion A1 from among the plurality of first emission openings 301OP1, and the number of the second emission openings arranged in portion A2 from among the plurality of second emission openings 301OP2 may be smaller than the number of the second emission openings arranged in portion B2 from among the plurality of second emission openings 301OP2. In this case, the number of the first emission openings arranged on one side of the first pixel opening 175OP1 in the first inclination direction (+id1 direction) from among the first emission openings 301OP1 and the number of the first emission openings arranged on another side of the first pixel opening 175OP1 in the opposite direction (−id1 direction) of the first inclination direction may be identical to the number of the first emission openings arranged in portion A1. In addition, the number of the second emission openings arranged on one side of the second pixel opening 175OP2 in the first inclination direction (+id1 direction) from among the second emission openings 301OP2 and the number of the second emission openings arranged on another side of the second pixel opening 175OP2 in the opposite direction (−id1 direction) of the first inclination direction may be identical to the number of the second emission openings arranged in portion B2. Through such configuration, even when the viewing angle at which the display region is seen changes, colors of an image displayed on the display region may not substantially change, or the change may be minimized. This may also be applied to embodiments described below and variations thereof.

The structure illustrated in FIG. 8 and the structure illustrated in FIG. 9 may be used concurrently. For example, while the structure of FIG. 8 is maintained, the area of each of the first emission openings arranged in portion A1 from among the plurality of first emission openings 301OP1 may be greater than the area of each of the first emission openings arranged in portion B1 from among the plurality of first emission openings 301OP1, and the area of each of the second emission openings arranged in portion B2 from among the plurality of second emission openings 301OP2 may be greater than the area of each of the second emission openings arranged in portion A2 from among the plurality of second emission openings 301OP2.

Or, the structure of the first organic light-emitting device 310 may be different from the structure of the second organic light-emitting device 320. For example, the first organic light-emitting device 310 may use the structure illustrated in FIG. 8, and the second organic light-emitting device 320 may use the structure illustrated in FIG. 9.

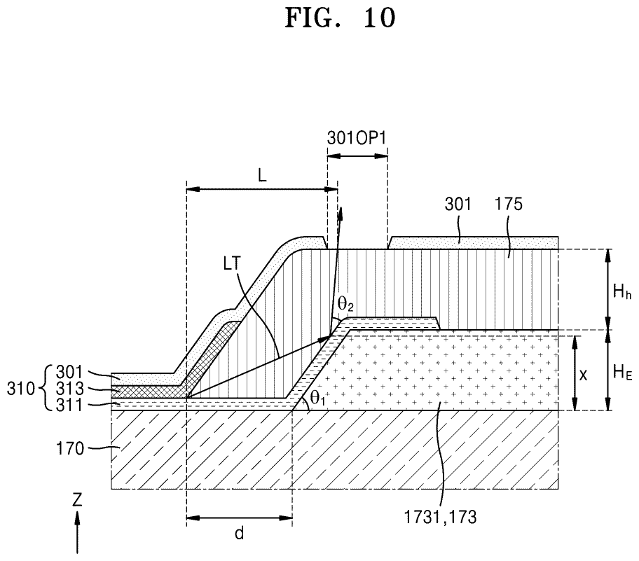

FIG. 10 is a schematic cross-sectional view of some components of a display apparatus according to an embodiment. As illustrated in FIG. 10, a distance between an end of the first intermediate layer 313 on the first pixel electrode 311 and an end of the first portion 1731 of the intermediate insulating layer 173 in the direction to the first pixel electrode 311 may be defined as d. In addition, H_{E} represents the height of the first portion 1731 of the intermediate insulating layer 173, and Hₕ represents the height (i.e., the maximum thickness) of the pixel-defining layer 175 on the first portion 1731. When considering a point of the first pixel electrode 311 located on the inner side surface of the first portion 1731 of the intermediate insulating layer 173, at which the light LT emitted from the end of the first intermediate layer 313 arrives, the height from the planarization layer 170 to the point may be defined as x. When a taper angle of the first portion 1731 of the intermediate insulating layer 173 is θ₁, and an angle between the light LT reflected on the first pixel electrode 311 and the surface of the first pixel electrode 311 is θ₂ at which the light LT is reflected, a horizontal length L from the end of the first intermediate layer 313 and the point of the pixel-defining layer 175 from which the light LT escapes may be represented by the following formula when θ₁+θ₂ is 90°:

$$L = d + \frac{x}{tan {θ}_{1}} + \frac{d sin {θ}_{1} cos ( {θ}_{1} + {θ}_{2} )}{sin {θ}_{2}}$$

When θ₁+θ₂ is less than 90°, the horizontal length L may be represented by the following formula:

$$L = d + \frac{x}{tan {θ}_{1}} + \frac{{H}_{h}}{tan ( {θ}_{1} - {θ}_{2} )}$$

θ₂ may be represented by the following formula:

$${θ}_{2} = {θ}_{1} - \frac{180}{π} {tan}^{- 1} ( \frac{x tan {θ}_{1}}{x + d tan {θ}_{1}} ) .$$

Accordingly, in any case, L may be represented by x, θ₁, d, and/or Hₕ.

θ₁ may be about 50° to about 60°, H_{E} may be about 2 micrometers (μm) to about 3 μm, d may be about 1.5 μm, and Hₕ may be 1 μm. Thus, when 01 is 55°, and H_{E} is 2.5 μm, L may be represented by using a function of x. As x is greater than or equal to 0 and less than or equal to H_{E}, according to the calculation, L may be 0.6 μm to about 2.4 μm. Accordingly, when the distance between the end of the first intermediate layer 313 on the first pixel electrode 311 and the end of the first emission opening 301OP1 in the direction to the first pixel electrode 311 is 0.6 μm, and the width of the first emission opening 301OP1 is 1.8 μm, light emitted from the first emission layer included in the first intermediate layer 313 and reflected from a portion of the first pixel electrode 311 located on the inner side surface of the first portion 1731 of the intermediate insulating layer 173 may be efficiently extracted to the outside through the first emission opening 301OP1 of the common electrode 301.

According to an embodiment, a display apparatus on which a high-quality image is displayed may be implemented. However, the scope of the disclosure is not limited to the above-mentioned effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first pixel electrode disposed on the substrate;
a pixel-defining layer covering an edge of the first pixel electrode and defining a first pixel opening exposing a central portion of the first pixel electrode;
an intermediate insulating layer interposed between the substrate and the pixel-defining layer and including a first portion defining a first intermediate opening having an area greater than an area of the first pixel opening in a plan view;
a first intermediate layer contacting the first pixel electrode through the first pixel opening and including a first emission layer; and
a common electrode disposed over the first pixel electrode with the first intermediate layer interposed therebetween and defining a plurality of first emission openings arranged outside the first pixel opening in the plan view.

2. The display apparatus of claim 1, wherein the first pixel electrode extends over the first portion of the intermediate insulating layer.

3. The display apparatus of claim 2, further comprising a thin-film transistor disposed under the first pixel electrode, wherein the first pixel electrode is electrically connected to the thin-film transistor through a contact hole passing through the first portion of the intermediate insulating layer.

4. The display apparatus of claim 1, wherein, in the plan view, the plurality of first emission openings are arranged along an edge of the first pixel opening.

5. The display apparatus of claim 4, wherein, in the plan view, a total area of first emission openings arranged on one side of the first pixel opening from among the plurality of first emission openings is greater than a total area of first emission openings arranged on another side of the first pixel opening from among the plurality of first emission openings.

6. The display apparatus of claim 4, wherein, in the plan view, an area of each of first emission openings arranged on one side of the first pixel opening from among the plurality of first emission openings is greater than an area of each of first emission openings arranged on another side of the first pixel opening from among the plurality of first emission openings.

7. The display apparatus of claim 4, wherein, in the plan view, a total number of first emission openings arranged on one side of the first pixel opening from among the plurality of first emission openings is greater than a total number of first emission openings arranged on another side of the first pixel opening from among the plurality of first emission openings.

8. The display apparatus of claim 7, wherein, in the plan view, an area of each of the first emission openings arranged on one side of the first pixel opening from among the plurality of first emission openings is equal to an area of each of the first emission openings arranged on another side of the first pixel opening from among the plurality of first emission openings.

9. The display apparatus of claim 7, wherein the plurality of first emission openings have a same area from each other in the plan view.

10. The display apparatus of claim 1, wherein, in the plan view, an end of at least one of the plurality of first emission openings in a direction to the center portion of the first pixel electrode is on the first pixel electrode.

11. The display apparatus of claim 1, wherein, in the plan view, an end of at least one of the plurality of first emission openings in a direction to the center portion of the first pixel electrode is between an edge of the first intermediate opening and the edge of the first pixel electrode.

12. The display apparatus of claim 1, wherein the intermediate insulating layer further includes a second portion interposed between the substrate and the first pixel electrode, disposed in the first intermediate opening in the plan view, and apart from the first portion.

13. The display apparatus of claim 12, wherein an edge of the first portion in a direction to the second portion includes a first inclined portion inclining with respect to a major surface of the substrate, and an edge of the second portion includes a second inclined portion inclining with respect to the major surface of the substrate.

14. The display apparatus of claim 12, wherein the second portion defines a recess or a hole corresponding to a center of the first pixel electrode.

15. The display apparatus of claim 14, wherein an inner side surface of the recess or the hole defined in the second portion includes a third inclined portion inclining with respect to a major surface of the substrate.

16. The display apparatus of claim 1, further comprising:
a second pixel electrode disposed on the substrate; and
a second intermediate layer contacting the second pixel electrode and including a second emission layer,
wherein the pixel-defining layer defines a second pixel opening exposing a central portion of the second pixel electrode and covers an edge of the second pixel electrode, and
the common electrode is disposed over the second pixel electrode with the second intermediate layer interposed therebetween and defines a plurality of second emission openings arranged outside the second pixel opening in the plan view.

17. The display apparatus of claim 16, wherein, from among layers included in the first intermediate layer, a layer other than the first emission layer is integrally formed with a corresponding layer from among layers included in the second intermediate layer, other than the second emission layer.

18. The display apparatus of claim 16, wherein, in the plan view, a total area of first emission openings arranged on one side of the first pixel opening from among the plurality of first emission openings is greater than a total area of first emission openings arranged on another side of the first pixel opening from among the plurality of first emission openings, and a total area of second emission openings arranged on one side of the second pixel opening from among the plurality of second emission openings is less than a total area of second emission openings arranged on another side of the second pixel opening from among the plurality of second emission openings.

19. The display apparatus of claim 16, wherein, in the plan view, an area of each of first emission openings arranged on one side of the first pixel opening from among the plurality of first emission openings is greater than an area of each of first emission openings arranged on another side of the first pixel opening from among the plurality of first emission openings, and an area of each of second emission openings arranged on one side of the second pixel opening from among the plurality of second emission openings is less than an area of each of second emission openings arranged on another side of the second pixel opening from among the plurality of second emission openings.

20. The display apparatus of claim 16, wherein, in the plan view, a total number of first emission openings arranged on one side of the first pixel opening from among the plurality of first emission openings is greater than a total number of first emission openings arranged on another side of the first pixel opening from among the plurality of first emission openings, and a total number of second emission openings arranged on one side of the second pixel opening from among the plurality of second emission openings is less than a total number of second emission openings arranged on another side of the second pixel opening from among the plurality of second emission openings.

21. The display apparatus of claim 20, wherein, in the plan view, an area of each of the first emission openings arranged on one side of the first pixel opening from among the plurality of first emission openings is equal to an area of each of the first emission openings arranged on another side of the first pixel opening from among the plurality of first emission openings, and an area of each of the second emission openings arranged on one side of the second pixel opening from among the plurality of second emission openings is equal to an area of each of the second emission openings arranged on another side of the second pixel opening from among the plurality of second emission openings.

22. The display apparatus of claim 20, wherein the plurality of first emission openings have a same area from each other, and the plurality of second emission openings have a same area from each other in the plan view.
